(19) United States
(12) Patent Application Publication
(10) Pub. No.: US 2023/0352403 A1
(43) Pub. Date: Nov. 2, 2023

(54) METHOD FOR TREATING AN OPTOELECTRONIC DEVICE

(71) Applicant: ALEDIA, Echirolles (FR)

(72) Inventors: Olivier Jeannin, Grenoble (FR); Erwan Dornel, Champagnier (FR); Frédéric Mercier, Saint-Nicolas-De-Macherin (FR); Matthieu Charbonnier, Fontaine (FR)

(73) Assignee: ALEDIA, Echirolles (FR)

(21) Appl. No.: 18/023,337

(22) PCT Filed: Aug. 19, 2021
(86) PCT No.: PCT/EP2021/073092

§ 371 Date: Feb. 24, 2023

(30) Foreign Application Priority Data
Aug. 28, 2020 (KR) 2008792

(51) Int. Cl. H01L 23/525; H01L 27/02; H01L 27/146; H01L 27/15

(52) U.S. Cl. CPC H01L 23/5258; H01L 27/0248; H01L 27/14643; H01L 27/156

(57) ABSTRACT

A method for treating a region of an optoelectronic device (Pix) further including a substrate adjacent to the region to be treated. The optoelectronic device includes, in the region to be treated, programmable elements configured to be modified when they are exposed to a laser beam. The method includes the exposure of at least one of the programmable elements to the laser beam focused through the substrate.

The present patent application claims the priority benefit of French patent application FR20/08792 which is herein incorporated by reference.

### TECHNICAL BACKGROUND

The present disclosure generally concerns a method for treating an optoelectronic device, particularly a method for modifying the optoelectronic device after its manufacturing.

### PRIOR ART

By optoelectronic devices, there is meant devices capable of converting an electric signal into an electromagnetic radiation or conversely, and particularly devices dedicated to the detection, the measurement, or the emission of an electromagnetic radiation. An example of application concerns a display screen comprising a support having distinct optoelectronic devices bonded thereto, each optoelectronic device comprising at least one light-emitting diode for the transmission of signals relative to an image pixel. Another example of application concerns an image sensor comprising a support having optoelectronic devices individually bonded thereto, each optoelectronic device comprising at least one photodiode for the capture of signals relative to an image pixel.

For certain applications, it is necessary to provide a step of modification of the optoelectronic device after its manufacturing.

A first example of application corresponds to the case of an optoelectronic device for which a calibration operation may be implemented after the manufacturing of the optoelectronic device, the calibration operation being likely to cause a modification of operating parameters of the optoelectronic device. As an example, for an optoelectronic device comprising light-emitting diodes for the display of an image pixel, the calibration operation may enable to set the white balance of the optoelectronic device.

For this purpose, it is known to provide a memory in the optoelectronic device into which data may be written after the calibration operation to modify the operation of the optoelectronic device. To perform the write operation in the memory of the optoelectronic device, it may then be necessary to provide on the optoelectronic device terminals of access to this memory. However, the desired dimensions of the optoelectronic device may not enable the presence of additional access terminals in addition to those provided for the normal operation of the optoelectronic device.

A second example of application corresponds to the case where the optoelectronic device comprises a system for protecting the optoelectronic device against electrostatic discharges (ESDs), particularly electrostatic discharges likely to occur during the method of manufacturing and handling of the optoelectronic device. Indeed, according to the structure of the protection system, it may be necessary to provide a step of deactivation of the protection system once the optoelectronic device is in place so that the optoelectronic device operates normally.

To perform the step of deactivation of the protection system, it may then be necessary to provide specific access terminals on the optoelectronic device. However, the desired dimensions of the optoelectronic device may not enable the presence of additional access terminals in addition to those provided for the normal operation of the optoelectronic device.

### SUMMARY OF THE INVENTION

An embodiment overcomes all or part of the disadvantages of the previously-described optoelectronic device treatment methods, particularly, methods for modifying the optoelectronic devices after their manufacturing.

According to an embodiment, the optoelectronic device comprises no specific access terminals to perform the treatment of the optoelectronic device.

An embodiment provides a method for treating a region of an optoelectronic device further comprising a substrate adjacent to the region to be treated, the optoelectronic device comprising, in the region to be treated, programmable elements configured to be modified when they are exposed to a laser beam, the method comprising the exposure of at least one of the programmable elements to the laser beam focused through the substrate.

According to an embodiment, each programmable element comprises a conductive track, the method comprising the interruption of the conductive track of at least one of the programmable elements by the focused laser beam.

According to an embodiment, the optoelectronic device comprises a one-time programmable memory comprising the programmable elements, the method comprising the exposure of a portion of said programmable elements to the focused laser beam.

According to an embodiment, the optoelectronic device comprises a system of protection against electrostatic discharges comprising the programmable elements, the method comprising the exposure of all the programmable elements to the focused laser beam.

According to an embodiment, the protection system comprises a circuit of interconnection of electronic components and of optoelectronic components via the programmable elements.

According to an embodiment, the conductive tracks are metallic or made of a non-metallic electrically-conductive material, particularly, doped single-crystal or polycrystalline silicon.

According to an embodiment, the optoelectronic device comprises light-emitting diodes and/or photodiodes.

According to an embodiment, the method comprises the exposure of the optoelectronic device to a pulse of the focused laser beam, the duration of said at least one pulse being in the range from 0.1 ps to 1,000 ps.

According to an embodiment, the method comprises the exposure of the optoelectronic device to said at least one pulse of the focused laser beam with a peak power in the range from 300 kW to 100 MW.

According to an embodiment, the method comprises the exposure of the optoelectronic device to said at least one pulse of the focused laser beam with a wavelength in the range from 1.2 μm to 4 μm.

According to an embodiment, the material forming the substrate is semiconductor.

According to an embodiment, the substrate is made of silicon, of germanium, or of a mixture or alloy of these compounds.

An embodiment also provides an optoelectronic device comprising a substrate and programmable elements in a stack resting on the substrate, at least one of the programmable elements having been modified by a laser beam focused through the substrate.

According to an embodiment, each programmable element comprises a conductive track, the conductive track of at least one of the programmable elements having been interrupted by the focused laser beam.

According to an embodiment, the optoelectronic device comprises a one-time programmable memory comprising the programmable elements, a portion of said programmable elements having been modified by the focused laser beam.

According to an embodiment, the optoelectronic device comprises a system of protection against electrostatic discharges comprising the programmable elements, the protection system being activated when all the programmable elements are not modified by the focused laser beam.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a partial simplified cross-section view of an embodiment of an optoelectronic device with light-emitting diodes;

FIG. 2 is a top view of a programmable element of the optoelectronic device shown in FIG. 1;

FIG. 3 shows an electronic diagram of a one-time programmable memory;

FIG. 4 is a top view of programmable elements of the one-time programmable memory shown in FIG. 3;

FIG. 5 shows an equivalent electric diagram of an embodiment of an optoelectronic device with light-emitting diodes comprising a system of protection against electrostatic discharges;

FIG. 6 shows an equivalent electric diagram of another embodiment of an optoelectronic device with light-emitting diodes comprising a system of protection against electrostatic discharges;

FIG. 7 illustrates an embodiment of a system for treating an optoelectronic device with a laser; and

FIG. 8 is a partial simplified cross-section view of a more detailed embodiment of the structure of a display pixel.

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. In particular, display pixel control circuits are well known by those skilled in the art and will not be described in detail. Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the drawings or to an optoelectronic device in a normal position of use. Unless specified otherwise, the expressions “around”, “approximately”, “substantially” and “in the order of” signify within 10%, and preferably within 5%. Further, it is here considered that the terms “insulating” and “conductive” respectively signify “electrically insulating” and “electrically conductive”.

Embodiments will be described in the case of an optoelectronic device used for the display of an image pixel, and in particular an optoelectronic device comprising light-emitting diodes. It should however be clear that these embodiments may be implemented for an optoelectronic device used for the acquisition of an image pixel, and in particular an optoelectronic device comprising photodiodes.

A pixel of an image corresponds to the unit element of the image displayed by a display screen. An optoelectronic device allowing the display of an image pixel is called display pixel hereafter. When the display screen is a color image display screen, it generally comprises, for the display of each image pixel, at least three emission and/or light intensity regulation components, also called display sub-pixels, which each emit a light radiation substantially in a single color (for example, red, green, or blue). The superposition of the radiations emitted by the three display sub-pixels provides the observer with the colored sensation corresponding to the pixel of the displayed image. In this case, the assembly formed by the three display sub-pixels used for the display of a pixel of an image is called display pixel of the display screen. When the display screen is a monochrome image display screen, it generally comprises a single light source for the display of each image pixel.

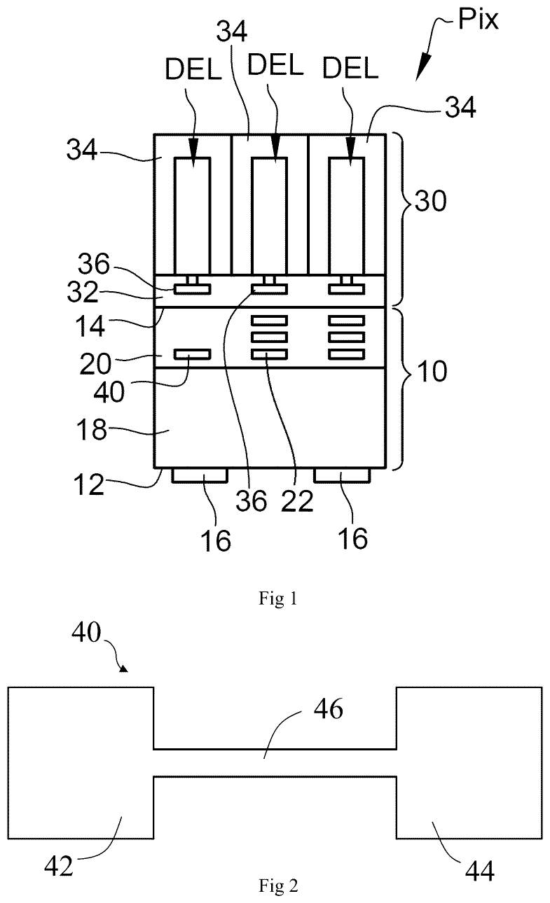

FIG. 1 is a partial simplified cross-section view of an embodiment of a display pixel Pix. A display screen may comprise from 10 to 10⁹ display pixels Pix. Each display pixel Pix may occupy in top view a surface area in the range from 1 μm² to 100 mm². The thickness of each display pixel Pix may be in the range from 1 μm to 6 mm.

Display pixel Pix comprises from bottom to top in FIG. 1:
an electronic circuit 10, called control circuit hereafter; and
an optoelectronic circuit 30.

Control circuit 10 comprises a lower surface 12 and an upper surface 14 opposite to lower surface 12, surfaces 12 and 14 being preferably parallel. Control circuit 10 further comprises conductive pads 16 on lower surface 12. Control circuit 10 may comprise a semiconductor substrate 18, a stack 20 of insulating layers covering substrate 18, and conductive tracks 22 of several metallization levels formed between the insulating layers of stack 20 and connected by conductive vias, not shown. Control circuit 10 may further comprise electronic components, not shown in FIG. 1, particularly transistors, formed inside and/or on top of substrate 18. An insulating layer, not shown, may cover semiconductor substrate 18 on the side opposite to stack 20 and delimit the lower surface 12 of control circuit 10. Control circuit 10 may further comprise through conductive vias, not shown, extending in substrate 18, across the entire thickness of substrate 18, and electrically insulated from the substrate, and enabling to electrically couple pads 16 to the front side of substrate 18. Semiconductor substrate 18 is for example a silicon substrate, particularly made of single-crystal silicon. The electronic components may then comprise insulated-gate field-effect transistors, also called MOS (Metal-Oxide Semiconductor) transistors. According to another embodiment, substrate 18 may correspond to a non-semiconductor substrate. According to an embodiment, the electronic components may comprise thin-film transistors, also called TFT (Thin-Film Transistor) transistors, and substrate 18 can then be omitted

Optoelectronic circuit 30 is bonded to the upper surface 14 of control circuit 10. As a variant, particularly when the electronic components comprise thin-film transistors, also called TFTs, control circuit 10 may be directly formed on optoelectronic circuit 30.

Optoelectronic circuit 30 comprises a support 32 having light-emitting diodes DEL, preferably at least three light-emitting diodes, formed thereon. The light-emitting diodes may for example be of planar shape, of wire shapes, or of pyramidal shape. Optoelectronic circuit 30 may comprise photoluminescent blocks 34 covering light-emitting diodes DEL on the side opposite to control circuit 10. Each photoluminescent block 34 is in front of at least one of light-emitting diodes DEL.

Optoelectronic circuit 30 comprises conductive elements 36 located in support 32, and connected to the electrodes of light-emitting diodes DEL. Optoelectronic circuit 30 is electrically coupled to control circuit 10 by conductive pads, which may correspond to conductive elements 36 and which are in contact with conductive pads of control circuit 10.

Preferably, optoelectronic circuit 30 only comprises the light-emitting diodes DEL and the conductive elements 36 of these light-emitting diodes DEL and control circuit 10 comprises all the electronic components necessary for the control of the light-emitting diodes DEL of optoelectronic circuit 30. As a variant, optoelectronic circuit 30 may also comprise other electronic components in addition to light-emitting diodes DEL.

According to an embodiment, the display pixel treatment operation, implemented after the manufacturing of display pixel Pix, comprises a laser treatment of display pixel Pix, as described in further detail hereafter. For this purpose, display pixel Pix comprises at least one programmable element 40 likely to be modified by the laser treatment. According to an embodiment, programmable element 40 comprises a conductive track likely to be interrupted by a laser treatment. Programmable element 40 may be provided in control circuit 10. According to an embodiment, programmable element 40 may be at least partly formed by some of conductive tracks 22, particularly by conductive tracks of the first metallization level of control circuit 10, which may be made of polysilicon, or by conductive tracks of another metallization level, which may be metallic.

FIG. 2 is a partial and simplified top view of an embodiment of a programmable element 40. Programmable element 40 comprises two access pads 42 and 44 and one conductive tracks 46 extending between the two access pads. Access pads 42 and 44 and conductive track 46 may correspond to conductive tracks 22 of control circuit 10 and/or to conductive elements 36 of optoelectronic circuit 30. Generally, conductive track 46 may be metallic or made of a non-metallic electrically-conductive material, particularly single-crystal or polycrystalline doped silicon. Each programmable element 40 once programmed is in one of first and second configurations. In the first configuration, track 46 is not interrupted and connects the two pads 42, 44. In the second configuration, track 46 is interrupted and does not connect the two pads 42, 44.

According to an embodiment, programmable element 40 forms a memory cell of a one-time programmable memory or OTP memory. In this embodiment, after the manufacturing of the optoelectronic device, the track 46 of the programmable element 40 of each memory cell is not interrupted so that programmable element 40 is in the first configuration. This corresponds to the storage in the memory cell of a binary piece of data in a first state. Calibration operations may then be performed for the optoelectronic device. The programming step comprises, for some of the memory cells, the interruption of the track 46 of the programmable element 40 of the memory cell to take programmable element 40 to the second configuration. This corresponds to the storage in the memory cell of a binary piece of data in a second state.

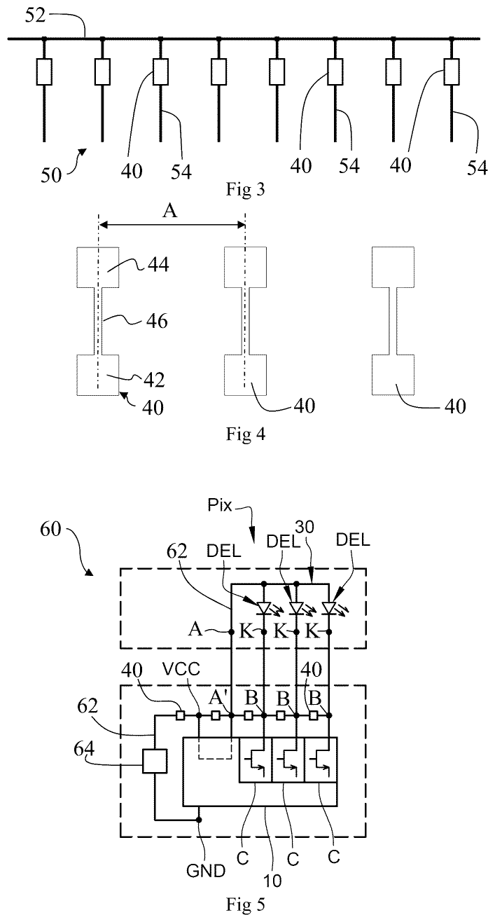

FIG. 3 is an electric diagram of an embodiment of an OTP memory 50. OTP memory 50 comprises a row of programmable elements 40. A terminal of each programmable element 40 is coupled, for example, connected, to a selection rail 52. The other terminal of each programmable element 40 is connected to a readout circuit, not shown, by a readout rail 54. The programming of memory 50 is obtained, for each programmable element 40, by the destruction, selective or not, of the conductive track 46 of this programmable element 40. In operation, the reading of the digital piece of data stored in memory 50 may be obtained by setting rail 52 to a reference potential and by reading the potentials on readout rails 54. As a variant, OTP memory 50 may comprise an array of memory cells arranged in rows and in columns.

According to another embodiment, programmable element 40 forms part of a system of protection of the display pixel against electrostatic discharges. In this embodiment, after the manufacturing of the display pixel, the track 46 of each programmable element 40 is not interrupted so that programmable element 40 is in the first configuration. The display pixel protection system is then activated. The programming step comprises, by laser treatment, the interruption of the track 46 of each programmable element 40. This enables to make the display pixel protection system inactive.

FIG. 4 is a partial and simplified top view of programmable elements 40 of the memory 50 of FIG. 3 or of a system of protection against electrostatic discharges. The programmable elements 40 of the display pixel may be formed by conductive tracks resting on a same layer. The programmable elements 40 of a pair of adjacent programmable elements are spaced apart by a distance A so that each programmable element 40 can be programmed separately from the adjacent programmable element. According to an embodiment, distance A is greater than 2 μm, preferably greater than 5 μm. According to an embodiment, there are no other electronic components or conductive tracks along the direction of stacking of the layers of stack 20 above and under conductive track 46 less than 10 μm away from conductive track 46.

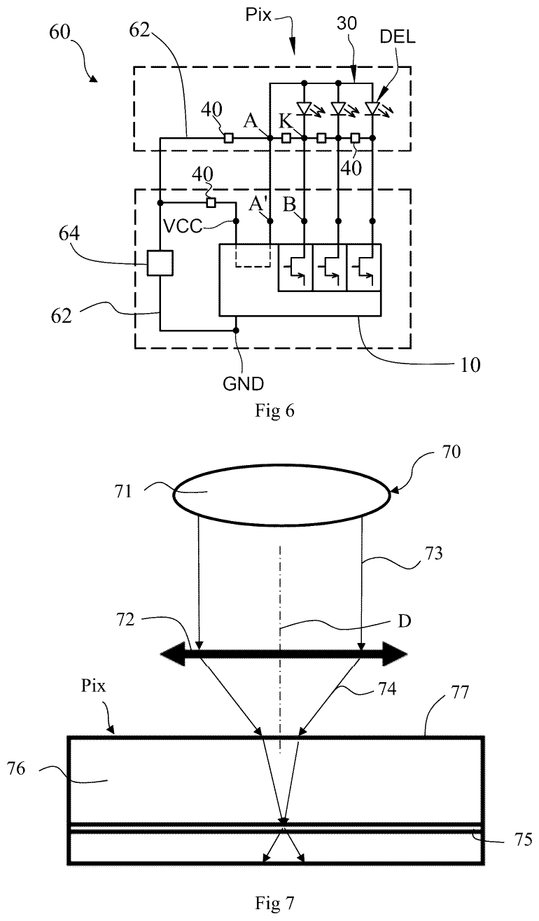

FIGS. 5 and 6 each show an embodiment of an equivalent electric diagram of a display pixel Pix comprising an ESD protection system 60. Display pixel Pix comprises all the elements of the display pixel shown in FIG. 1 and further comprises a system of protection against ESDs. Protection system 60 aims at forming a preferred path for the current flow in the case of an ESD to avoid a degradation of the light-emitting diodes DEL of optoelectronic circuit 30 and/or of the electronic components of control circuit 10. Protection system 60 is electrically connected to all the electronic components of control circuit 10 and/or of optoelectronic circuit 30 to be protected against ESDs by electric links 62 shown in thick lines in FIGS. 5 and 6. Protection system 60 is further coupled to one of the conductive pads 16 of display pixel Pix, which may be set to ground GND. According to an embodiment, protection system 60 corresponds to a short-circuit provided between one of conductive pads 16 and electric links 62. As a variant, protection system 60 may comprise one or a plurality of electronic components 64, for example, a diode.

In FIGS. 5 and 6, optoelectronic circuit 30 comprises at least three light-emitting diodes DEL, light-emitting diodes DEL having a common anode electrode A and comprising distinct cathode electrodes K. Further, in FIGS. 5 and 6, control circuit 10 comprises, for each light-emitting diode DEL, a circuit with MOS transistors C for controlling light-emitting diode DEL comprising a terminal B which is connected to the cathode K of light-emitting diode DEL in operation. Further, control circuit 10 comprises a terminal A′ connected to the common anode electrode A of light-emitting diodes DEL in operation, a terminal GND intended in operation to receive a low reference potential, for example, the ground, and a terminal VCC intended to receive in operation a high reference potential. The high and low potentials may be applied between the conductive pads 16 of control circuit 10 in operation. According to an embodiment, terminals B, A′, and VCC may correspond to conductive tracks 22 present in the stack 20 of electronic circuit 10.

Protection circuit 60 comprises programmable elements 40 series-connected with conductive tracks 62. Before the programming, all the programmable elements 40 are in the first configuration, whereby they behave as on switches. After the programming, all the programmable elements 40 are in the second configuration, whereby they behave as off switches. Programmable elements 40 are located on the path of conductive tracks 62 at the locations where an interruption of the electric path is desired after the programming.

In the equivalent electric diagram of FIG. 5, protection system 60 is connected to terminals B, A′, and VCC of display pixel Pix, for example, by conductive tracks of one of the metallization levels of electronic circuit 10 and protection system 60 is connected to terminal GND. The programming step causes the interruption of electric links 62 between terminals B, A′, and VCC.

In the equivalent electric diagram of FIG. 6, protection system 60 is connected to terminals A and K of display pixel Pix for example by the conductive elements of optoelectronic circuit 30 and protection system 60 is connected to terminal GND of display pixel Pix. Protection system 60 may further be connected to terminal VCC of display pixel Pix, for example, by conductive tracks of one of the metallization levels of the electronic circuit, to ensure that all the possible current flow paths during electrostatic discharges are protected. The programming step causes, for each display pixel Pix, the interruption of the electric links 62 between terminals A and K.

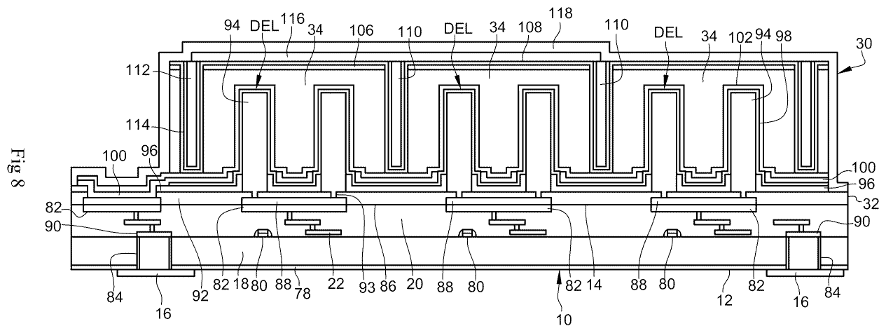

FIG. 7 is a partial and simplified cross-section view of an embodiment of a system 70 for treating the display pixel Pix of FIG. 1.

Treatment system 70 comprises a laser source 71 and an optical focusing device 72 having an optical axis D. Source 71 is adapted to delivering an incident laser beam 73 to focusing device 72, which delivers a convergent laser beam 74. Optical focusing device 72 may comprise one optical component, two optical components, or more than two optical components, an optical component for example corresponding to a lens. Preferably, incident laser beam 73 is substantially collimated along the optical axis D of optical device 72.

There has been shown in FIG. 7 a region 75 of display pixel Pix comprising the programmable elements to be programmed. Generally, to reach the region to be treated 75, the laser has to cross a portion 76, called substrate hereafter, of display pixel Pix, and possibly of a support having display pixel Pix bonded thereto. Substrate 76 comprises a surface 77 receiving the laser beam. Preferably, surface 77 is planar and polished. According to an embodiment, the treatment is performed while display pixel Pix is not bonded to a support on the side of control circuit 10. In this case, surface 77 may correspond to surface 12 of electronic circuit 10 and the treatment of display pixel Pix is preferably performed on the side of surface 12 of electronic circuit 10. According to another embodiment, the treatment is performed while display pixel Pix is bonded to a support on the side of control circuit 10. In this case, the treatment of display pixel Pix may be performed on the side of surface 12 of control circuit 10, through the support having electronic circuit 10 resting thereon or may be performed through optoelectronic circuit 30.

According to an embodiment, the thickness of substrate 76 is in the range from 50 μm to 3 mm. According to an embodiment, an antireflection layer, not shown, is provided on exposure surface 77. Substrate 76 may comprise at least one semiconductor material, for example, silicon, in particular single-crystal silicon, and/or at least one electrically-insulating material, and/or at least one electrically-conducting material.

According to an embodiment, the treatment corresponds to the exposure of portions of the region to be treated 75 to allow, for each exposed portion, the destruction of the programmable element located in this portion. The laser beam may be adapted to be sufficiently high to destroy the programmable element, and sufficiently low to avoid damaging the neighboring elements.

According to an embodiment, the wavelength of the laser beam 74 supplied by treatment system 70 is greater than the wavelength corresponding to the bandgap of the material mainly forming substrate 76, preferably by at least 500 nm, more preferably by at least 700 nm. This advantageously enables to decrease interactions between laser beam 74 and substrate 76 during the crossing of substrate 76 by laser beam 74. According to an embodiment, the wavelength of the laser beam 74 delivered by treatment system 70 is not greater than the wavelength corresponding to the bandgap of the material forming substrate 76, preferably by more than 2,500 nm. This advantageously enables to more easily provide a laser beam forming a laser spot of small dimensions.

In the case where substrate 76 is mainly made of silicon which has a 1.14-eV bandgap, which corresponds to a 1.1-μm wavelength, the wavelength of laser beam 74 is selected to be equal to approximately 2 μm. In the case where substrate 76 is mainly made of germanium which has a 0.661-eV bandgap, which corresponds to a 1.87-μm wavelength, the wavelength of laser beam 74 is selected to be equal to approximately 2 μm or 2.35 μm.

According to an embodiment, laser beam 74 is polarized. According to an embodiment, laser beam 74 is polarized according to a rectilinear polarization. This advantageously enables to improve interactions of laser beam 74 with the region 75 to be treated. According to another embodiment, laser beam 74 is polarized according to a circular polarization. This advantageously enables to favor the propagation of laser beam 74 through substrate 76.

According to an embodiment, laser beam 74 is emitted by treatment system 70 in the form of a pulse, of two pulses, or of more than two pulses, each pulse having a duration in the range from 0.1 ps to 1,000 ps. The peak power of the laser beam for each pulse is in the range from 300 kW to 100 MW. The fact of using pulses longer than pulses of durations shorter than 100 femtoseconds enables to decrease the peak power of laser beam 74 and thus to decrease non-linear interactions of laser beam 74 with substrate 76. The fact of using pulses shorter than nanosecond pulses enables to avoid an unwanted heating outside of the region 75 to be treated, likely to cause a deterioration of the layers next to the region 75 to be treated.

In the embodiment where the programmable elements form part of a one-time programmable memory, the display pixel programming treatment may be implemented once tests have been performed on the display pixel and the programming of the OTP memory may depend on the results of the tests. According to an embodiment, the tests may comprise a measurement of display properties of the display pixel, for example, the white balance, and the data written into the OTP memory depend on the performed measurements. In operation, the display properties of the display pixel are modified according to the data written into the OTP memory, which may be read by the control circuit.

In the embodiment where the programmable elements form part of a system of protection against electrostatic discharges, the treatment for programming the display pixel may be implemented once the display pixel has been placed on the final support. Thereby, a protection against electrostatic discharges is obtained all along the manipulation of the display pixel. Advantageously, since the system of protection against electrostatic discharges is made inactive after the programming treatment, the system of protection against electrostatic discharges may essentially comprise conductive tracks and be of small dimensions.

FIG. 8 is a partial simplified cross-section view of a more detailed embodiment of display pixel Pix.

According to an embodiment, the control circuit 10 of display pixel Pix comprises from bottom to top in FIG. 8:
semiconductor substrate 18, for example, single-crystal silicon, an insulating layer 78 on the side of lower surface 12, and the two conductive pads 16;
MOS transistors 80, formed inside and on top of substrate 18;
stack 20 of insulating layers, for example, made of silicon oxide and/or of silicon nitride, covering substrate 18 and the conductive tracks 22 of a plurality of metallization levels formed between the insulating layers of the stack 20, having in particular pads 82 exposed on the upper surface 14 of electronic circuit 10, where the conductive tracks 22 of the first metallization level may be made of polysilicon and particularly form the gates of MOS transistors 80 and where the conductive tracks 22 of the other metallization levels may be metal tracks, for example, made of aluminum, of silver, of copper, or of zinc; and
conductive and laterally-insulated vias 84, also called TSVs (Through Silicon Vias) crossing substrate 18 and coupling pads 16 to pads 90 of the first metallization level of stack 20.

According to an embodiment, the optoelectronic circuit 30 of display pixel Pix comprises from bottom to top in FIG. 8:
support 32 comprising a lower surface 86 in contact with upper surface 14 and comprising conductive pads 88 exposed on lower surface 86, in contact with pads 82, and a multilayer insulating structure 92, for example, made of silicon oxide or of silicon nitride, extending between pads 88 and covering pads 88 and comprising openings 93 exposing portions of pads 88;
microwires or nanowires 94, called wires hereafter (six wires being shown), each wire 94 being in contact with one of pads 88 through one of opening 93;
an insulating layer 96 extending on the lateral sides of a lower portion of each wire 94 and extending on insulating layer 92 between wires 94;
a shell 98 comprising a stack of semiconductor layers covering an upper portion of each wire 94 and extending on insulating layer 96 between wires 94, shell 98 particularly comprising an active layer which is the layer from which most of the radiation supplied by the light-emitting diode is emitted and comprising, for example, confinement means, such as multiple quantum wells;
a conductive and reflective layer 100, extending on shell 98 between wires 94;
a layer 102 forming an electrode covering, for each wire 94, shell 98 and further extending on conductive layer 100 between wires 94, electrode layer 102 being adapted to letting through the electromagnetic radiation emitted by the light-emitting diodes and being formed of a transparent and conductive material such as indium-tin oxide (or ITO), aluminum- or gallium-doped zinc oxide, or graphene;
photoluminescent blocks 34 covering certain assemblies of light-emitting diodes DEL or blocks transparent to the radiation emitted by the light-emitting diodes, each photoluminescent block comprising luminophores adapted, when they are excited by the light emitted by the associated light-emitting diodes DEL, to emitting light at a wavelength different from the wavelength of the light emitted by the associated light-emitting diodes DEL;
an insulating layer 106 covering the upper surface of each block 34, which insulating layer 106 may not be present;
a protection layer 108 covering insulating layers 106, the lateral surfaces of blocks 34, and the electrode layer 102 between blocks 104;
walls 110 between blocks 104, where each wall 110 may comprise a core 112 surrounded with a coating 114 reflective at the wavelength of the radiation emitted by photoluminescent blocks 34 and/or light-emitting diodes DEL;
a color filter 116 covering at least some of photoluminescent blocks 34; and
an encapsulation layer 118 covering the entire structure.

Each wire 94 for example has a mean diameter, for example corresponding to the diameter of the disk having the same area as the cross-section of wire 94, in the range from 5 nm to 5 μm, preferably from 100 nm to 2 μm, more preferably from 200 nm to 1.5 μm, and a height greater than or equal to 1 time, preferably greater than or equal to 3 times, and more preferably still greater than or equal to 5 times the mean diameter, particularly greater than 500 nm, preferably in the range from 1 μm to 50 μm. Wires 94 comprise at least one semiconductor material. The semiconductor material may be silicon, germanium, silicon carbide, a III-V compound, for example, GaN, AlN, InN, InGaN, AlGaN, or AlInGaN, a II-VI compound, or a combination of at least two of these compounds.

According to an embodiment, light-emitting diodes DEL are adapted to emitting blue light, that is, a radiation having a wavelength in the range from 430 nm to 490 nm. According to an embodiment, the first wavelength corresponds to green light and is in the range from 510 nm to 570 nm. According to an embodiment, the second wavelength corresponds to red light and is in the range from 600 nm to 720 nm. According to another embodiment, light-emitting diodes DEL are for example adapted to emitting an ultraviolet radiation. According to an embodiment, the first wavelength corresponds to blue light and is within the range from 430 nm to 490 nm. According to an embodiment, the second wavelength corresponds to green light and is within the range from 510 nm to 570 nm. According to an embodiment, the third wavelength corresponds to red light and is within the range from 600 nm to 720 nm.

Various embodiments and variants have been described. Those skilled in the art will understand that certain features of these various embodiments and variants may be combined, and other variants will occur to those skilled in the art. In particular, the embodiment where the programmable elements form part of a one-time programmable memory and the embodiment where the programmable elements form part of a system of protection against electrostatic discharges may be combined. The display pixel may then both comprise programmable elements which form part of a one-time programmable memory and programmable elements which form part of an ESD system.

Finally, the practical implementation of the described embodiments and variations is within the abilities of those skilled in the art based on the functional indications given hereabove. In particular, although embodiments have been described in the case of display pixels with light-emitting diodes comprising microwires or nanowires, it should be clear that these embodiments may concern a display pixel with light-emitting diodes comprising pyramids of micrometer- or nanometer-range size, a pyramid being a three-dimensional structure having a portion of elongated conical or pyramidal shape. This pyramidal structure may be truncated, that is, the top of the cone is absent and replaced with a flat area. The base of the pyramid is inscribed within a polygon having a side length from 100 nm to 10 μm, preferably from 1 to 3 μm. The polygon forming the base of the pyramid may be a hexagon. The height of the pyramid between the base of the pyramid and the apex or the top plateau varies from 100 nm to 20 μm, preferably from 1 μm to 10 μm. Further, although embodiments have been described in the case of display pixels comprising light-emitting diodes comprising microwires or nanowires, it should be clear that these embodiments may concern a display pixel comprising planar light-emitting diodes where each light-emitting diode is formed by a stack of planar semiconductor layers.

1. Method for treating a region of an optoelectronic device further comprising a substrate adjacent to the region to be treated, the optoelectronic device comprising, in the region to be treated, programmable elements configured to be modified when they are exposed to a laser beam, the method comprising the exposure of at least one of the programmable elements to the laser beam focused through the substrate.

2. Method according to claim 1, wherein each programmable element comprises a conductive track, the method comprising the interruption of the conductive track of at least one of the programmable elements by the focused laser beam.

3. Method according to claim 1, wherein the optoelectronic device comprises a one-time programmable memory comprising the programmable elements, the method comprising the exposure of a portion of said programmable elements to the focused laser beam.

4. Method according to claim 1, wherein the optoelectronic device comprises a system of protection against electrostatic discharges comprising the programmable elements, the method comprising the exposure of all the programmable elements to the focused laser beam.

5. Method according to claim 4, wherein the protection system comprises a circuit of interconnection of electronic components and of optoelectronic components via the programmable elements.

6. Method according to claim 2, wherein the conductive tracks are metallic or made of a non-metallic electrically conductive material, in particular monocrystalline or polycrystalline doped silicon.

7. Method according to claim 1, wherein the optoelectronic device comprises light-emitting diodes and/or photodiodes.

8. Method according to claim 1, comprising the exposure of the optoelectronic device to at least one pulse of the focused laser beam, the duration of said at least one pulse being in the range from 0.1 ps to 1,000 ps.

9. Method according to claim 8, comprising the exposure of the optoelectronic device to said at least one pulse of the focused laser beam with a peak power in the range from 300 kW to 100 MW.

10. Method according to claim 8, comprising the exposure of the optoelectronic device to said at least one pulse of the focused laser beam with a wavelength in the range from 1.2 μm to 4 μm.

11. Method according to claim 1, wherein the material forming the substrate is semiconductor.

12. Method according to claim 11, wherein the substrate is made of silicon, of germanium, or of a mixture or alloy of these compounds.

13. Optoelectronic device comprising a substrate and programmable elements in a stack resting on the substrate, at least one of the programmable elements having been modified by a laser beam focused through the substrate.

14. Optoelectronic device according to claim 13, wherein each programmable element comprises a conductive track, the conductive track of at least one of the programmable elements having been interrupted by the focused laser beam.

15. Optoelectronic device according to claim 13, wherein the optoelectronic device comprises a one-time programmable memory comprising the programmable elements, a portion of said programmable elements having been modified by the focused laser beam.

16. Optoelectronic device according to claim 13, wherein the optoelectronic device comprises a system of protection against electrostatic discharges comprising the programmable elements, the protection system being activated when all the programmable elements are not modified by the focused laser beam.

17. Optoelectronic device according to claim 16, wherein the protection system comprises a circuit of interconnection of electronic components and of optoelectronic components via the programmable elements.

18. Optoelectronic device according to claim 14, wherein the conductive tracks are metallic or made of a non-metallic electrically conductive material, in particular monocrystalline or polycrystalline doped silicon.

19. Optoelectronic device according to claim 13, wherein the optoelectronic device comprises light-emitting diodes and/or photodiodes.

20. Optoelectronic device according to claim 13, wherein the material forming the substrate is semiconductor.

21. Optoelectronic device according to claim 20, wherein the substrate is made of silicon, of germanium, or of a mixture or alloy of these compounds.
